(19) United States
(12) Patent Application Publication
(10) Pub. No.: US 2023/0268234 A1
(43) Pub. Date: Aug. 24, 2023

(54) METHOD FOR MONITORING BUBBLE BREAKUP DURING CMP

(71) Applicant: Shanghai Huali Integrated Circuit Corporation, Shanghai (CN)

(72) Inventors: Yurong CAO, Shanghai (CN); Hu LI, Shanghai (CN)

(73) Assignee: Shanghai Huali Integrated Circuit Corporation, Shanghai, CN (CN)

(21) Appl. No.: 18/306,001

(22) Filed: Apr. 24, 2023

(30) Foreign Application Priority Data
Jul. 12, 2022 (CN) 202210817452.3

(51) Int. Cl. H01L 21/66; H01L 21/687; B24B 49/10

(52) U.S. Cl. CPC H01L 22/14; H01L 21/68764; B24B 49/10

(57) ABSTRACT

The present application provides a method for monitoring bubble breakup during CMP, wherein a bonded wafer is formed by bonding of respective first surfaces of first and second wafers, and the magnitude of the current required to drive rotation of the bonded wafer is monitored from the start of the polishing; according to the change of the monitored current driving the rotation of the first wafer, it is determined whether there is bubble rupture at a bonding surface; if the current is increased instantaneously before the bonding surface is exposed by the polishing, bubbles generated at the bonding surface rupture; and if the magnitude of the current is constant before the end of the polishing, no bubble is generated at the bonding surface or generated bubbles do not rupture.

### CROSS-REFERENCES TO RELATED APPLICATIONS

This application claims priority to Chinese patent application No. CN 202210817452.3, filed on Jul. 12, 2022 at CNIPA, and entitled “METHOD FOR MONITORING BUBBLE BREAKUP DURING CMP”, the disclosure of which is incorporated herein by reference in entirety.

### TECHNICAL FIELD

The present application relates to the field of semiconductor technology, and in particular to a method for monitoring bubble breakup during CMP.

### BACKGROUND

In a BSI process, the bubble defect may emerge after two wafers are bonded, i.e., small bubbles are present between two bonded wafers. Then, bubbles may rupture during polishing upon the bonded wafers with the bubble defect arrive at a CMP station. After the bubble rupture, wafers would be scratched due to fallen wafer slags. Therefore, it is especially important to timely monitor the bubbles for breakup to reduce the impact on more subsequent wafers.

### BRIEF SUMMARY

In view of the above described shortcomings in the prior art, it is an object of the present application to provide a method for monitoring bubble breakup during CMP for solving the problem of the prior art in which the wafer is scratched in a subsequent process by bubbles generated at the bonding surface when wafer bonding as well as solving the time-consuming labor-intensive problem for traditionally manual observation of the bubble defect generated upon wafer bonding.

To achieve the above and other related purposes, the present application provides a method for monitoring bubble breakup during CMP, including at least:

step I. providing a bonded wafer formed by bonding a first wafer and a second wafer; the first wafer and second wafer including a first surface and a second surface, respectively; and the bonded wafer being formed by bonding respective first surfaces of the first wafer and second wafer, wherein mutually bonded surfaces are to form a bonding surface;

step II. performing chemical mechanical polishing on the second surface of the first wafer to gradually reduce the thickness of the first wafer, the bonded wafer being rotated during the polishing, the second surface of the first wafer and the polishing pad being contacted, so as to generate a friction force and relative motion of the two, and monitoring the magnitude of the current required to drive rotation of the bonded wafer from the start of the polishing; and

step III. according to the change of the monitored current driving rotation of the first wafer, determining whether there is bubble rupture at the bonding surface during the polishing, wherein if the current is increased instantaneously before the end of the polishing, bubbles are produced at the bonding surface during the bonding in step I, and the bubbles rupture when the current monitored during the polishing is increased instantaneously; and if the magnitude of the current is constant before the end of the polishing, no bubble is produced at the bonding surface during the bonding in step I or the produced bubbles do not rupture during the entire polishing.

According to some embodiments, the respective first surfaces of the first wafer and second wafer in step I are front surfaces, and the respective second surfaces of the first wafer and second wafer are back surfaces.

According to some embodiments, the bonded wafer is rotated by driving by a polishing head during the chemical mechanical polishing in step II.

According to some embodiments, the magnitude of the current required to drive rotation of the first wafer is monitored in step II by a data monitoring system in a chemical mechanical polishing machine.

According to some embodiments, from the start of the polishing in step II, the friction force between the second surface of the first wafer and the polishing pad is changed from large to small and then is stabilized; as polishing is proceeded, when there is a transient increase in the current in step III, the friction force between the second surface of the first wafer and the polishing pad is increased again.

According to some embodiments, the change trend of the magnitude of the current required to drive rotation of the bonded wafer in step II is from large to small from the start of polishing until the transient increase in the current in step III.

According to some embodiments, from the start of the polishing in step II, if the magnitude of the monitored current is constant before the end of the polishing in step III, the friction force between the second surface of the first wafer and the polishing pad is changed from large to small from the start of polishing and then stabilized.

According to some embodiments, the method further includes step IV: triggering a machine alarm when the monitored current is increased instantaneously during polishing in step III.

As described above, the method of the present application for monitoring bubble breakup during CMP has the following beneficial effect: the present application proposes a method that can timely monitor breakup at a bonding surface of bonded wafers during CMP without affecting chemical mechanical polishing for wafers, effectively reducing the possibility of subsequent scratched wafers, while improving the production efficiency and reducing economic losses.

### BRIEF DESCRIPTION OF THE DRAWINGS

FIG. 1 shows a flow chart of the method of the present application for monitoring bubble breakup during CMP; and

FIG. 2 shows a simulation view of the change trend of the monitored current driving rotation of the bonded wafer with the polishing time during polishing in the present application.

### DETAILED DESCRIPTION OF THE DISCLOSURE

The implementation of the application is illustrated in the following by specific embodiments, and other advantages and efficacy of the present application can be readily understood by those skilled in the art from the disclosure in the description. The present application may also be implemented or applied by further different specific implementations, and details in the description may be modified or changed in various ways based on different views and applications without departing from the spirit of the present application.

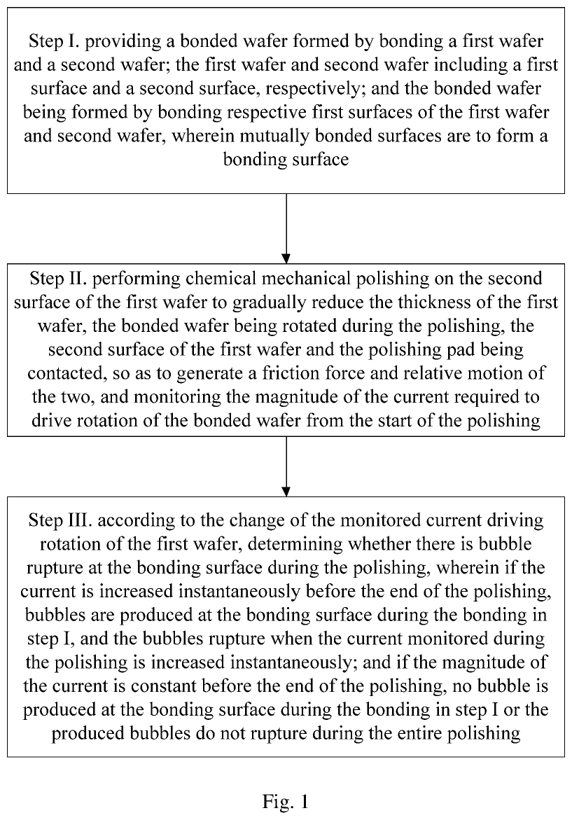

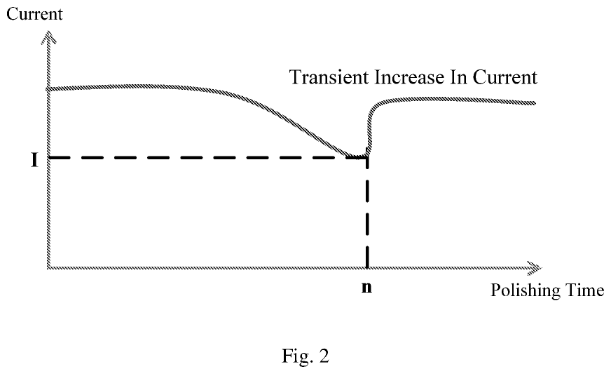

Please refer to FIGS. 1 to 2. It should be noted that the illustrations provided in the embodiments schematically illustrate the basic concept of the application, and the figures only show components related to the application and are not draw according to the number, shape and size of components in actual implementation, and the pattern, number and proportion of the components in actual implementation may be arbitrarily changed, and the layout pattern of the components may be more complex.

The present application provides a method for monitoring bubble breakup during CMP, referring to FIG. 1, which shows a flow chart of the method of the present application for monitoring bubble breakup during CMP, and the method includes at least the following steps:

step I. providing a bonded wafer formed by bonding a first wafer and a second wafer; the first wafer and second wafer including a first surface and a second surface, respectively; and the bonded wafer being formed by bonding respective first surfaces of the first wafer and second wafer, wherein mutually bonded surfaces are to form a bonding surface.

Further in the application, in the embodiment, the respective first surfaces of the first wafer and second wafer in step I are front surfaces, and the respective second surfaces of the first wafer and second wafer are back surfaces. That is, the respective first surfaces of the first wafer and second wafer in the present application are surfaces for forming a graphic structure. And respective back surfaces thereof are surfaces for bonding and thinning.

The method includes step II: performing chemical mechanical polishing on the second surface of the first wafer to gradually reduce the thickness of the first wafer, the bonded wafer being rotated during the polishing, the second surface of the first wafer and the polishing pad being contacted, so as to generate a friction force and relative motion of the two, and monitoring the magnitude of the current required to drive rotation of the bonded wafer from the start of the polishing; that is, in step II, after bonding, the second surface of the first wafer is an exposed surface, the first wafer is thinned starting from the second surface of the first wafer, and the thinning method is employed as the chemical mechanical polishing (CMP), during which the thickness of the first wafer is gradually reduced from the second surface thereof. Further in the application, during the chemical mechanical polishing in step II of the embodiment, the bonded wafer is rotated by driving by a polishing head. Thus, the second surface of the first wafer and the polishing pad are in contact with each other to generate a friction force and relative motion of the two, and the magnitude of the current required to drive rotation of the bonded wafer is monitored from the start of polishing.

Further in the application, in the embodiment, the magnitude of the current required to drive rotation of the first wafer is monitored in step II by a data monitoring system in a chemical mechanical polishing machine.

The method includes step III: according to the change of the monitored current driving rotation of the first wafer, determining whether there is bubble rupture at the bonding surface during the polishing, wherein if the current is increased instantaneously before the end of the polishing, bubbles are produced at the bonding surface during the bonding in step I, and the bubbles rupture when the current monitored during the polishing is increased instantaneously; and if the magnitude of the current is constant before the end of the polishing, no bubble is produced at the bonding surface during the bonding in step I or the produced bubbles do not rupture during the entire polishing. That is, when the bubbles rupture, the polishing results in the exposure of the bonding surface in the area with bubbles.

Further in the application, in the embodiment, from the start of the polishing in step II, the friction force between the second surface of the first wafer and the polishing pad is changed from large to small and then is stabilized; as polishing is proceeded, when there is a transient increase in the current in step III, the friction force between the second surface of the first wafer and the polishing pad is increased again.

Further in the application, in the embodiment, the change trend of the magnitude of the current required to drive rotation of the bonded wafer in step II is from large to small from the start of polishing until the transient increase in the current in step III.

Referring to FIG. 2, it shows a simulation view of the change trend of the monitored current driving rotation of the bonded wafer with the polishing time during polishing in the present application. Further in the application, in the embodiment, from the start of the polishing in step II, if the magnitude of the monitored current is constant before the end of the polishing in step III, the friction force between the second surface of the first wafer and the polishing pad is changed from large to small from the start of polishing and then stabilized. When the polishing time is n, the corresponding current is I. This current is the corresponding minimum current before the instantaneous increase.

Further, the method of the present application further includes step IV: triggering a machine alarm when the monitored current is increased instantaneously during polishing in step III.

In the present application, when the machine alarm is triggered, it means the defect of bubble rupture at the bonding surface of the bonded wafer during polishing, generating wafer slags in the chemical mechanical polishing machine, and when the machine is used to perform polishing for subsequent wafers, it would have been easy to produce scratches. Therefore, the wafer slags in the machine should be removed in time. At the same time, in the present application, by monitoring the change of the signal of the driving current and also by an alarm system for alarming, the manual monitoring time can be avoided, greatly shorting the process time and facilitating to improve the production efficiency.

In summary, the present application proposes a method that can timely monitor breakup at a bonding surface of bonded wafers during CMP without affecting chemical mechanical polishing for wafers, effectively reducing the possibility of subsequent scratched wafers, while improving the production efficiency and reducing economic losses. Therefore, the present application effectively overcomes the shortcomings of the prior art and has high industrial value.

The above embodiments are only illustrative of the principle of the application and effects thereof, and are not intended to limit the application. Any person skilled in the art may modify or change the above embodiments without departing from the spirit and scope of the present application. Therefore, all equivalent modifications or alterations made by those skilled in the art shall still be covered by the claims of the present application without departing from the spirit and technical ideas revealed by the present application.

What is claimed is:

1. A method for monitoring bubble breakup during CMP, comprising at least:
step I. providing a bonded wafer formed by bonding a first wafer and a second wafer; the first wafer and second wafer comprising a first surface and a second surface, respectively; and the bonded wafer being formed by bonding respective first surfaces of the first wafer and second wafer, wherein mutually bonded surfaces are to form a bonding surface;
step II. performing chemical mechanical polishing on the second surface of the first wafer to gradually reduce the thickness of the first wafer, the bonded wafer being rotated during the polishing, the second surface of the first wafer and the polishing pad being contacted, so as to generate a friction force and relative motion of the two, and monitoring the magnitude of the current required to drive rotation of the bonded wafer from the start of the polishing; and
step III. according to the change of the monitored current driving rotation of the first wafer, determining whether there is bubble rupture at the bonding surface during the polishing, wherein if the current is increased instantaneously before the end of the polishing, bubbles are produced at the bonding surface during the bonding in step I, and the bubbles rupture when the current monitored during the polishing is increased instantaneously; and if the magnitude of the current is constant before the end of the polishing, no bubble is produced at the bonding surface during the bonding in step I or the produced bubbles do not rupture during the entire polishing.

2. The method for monitoring bubble breakup during CMP according to claim 1, wherein the respective first surfaces of the first wafer and second wafer in step I are front surfaces, and the respective second surfaces of the first wafer and second wafer are back surfaces.

3. The method for monitoring bubble breakup during CMP according to claim 2, wherein, the bonded wafer is rotated by driving by a polishing head during the chemical mechanical polishing in step II.

4. The method for monitoring bubble breakup during CMP according to claim 3, wherein, the magnitude of the current required to drive rotation of the first wafer is monitored in step II by a data monitoring system in a chemical mechanical polishing machine.

5. The method for monitoring bubble breakup during CMP according to claim 4, wherein from the start of the polishing in step II, the friction force between the second surface of the first wafer and the polishing pad is changed from large to small and then is stabilized; as polishing is proceeded, when there is a transient increase in the current in step III, the friction force between the second surface of the first wafer and the polishing pad is increased again.

6. The method for monitoring bubble breakup during CMP according to claim 5, wherein the change trend of the magnitude of the current required to drive rotation of the bonded wafer in step II is from large to small from the start of polishing until the transient increase in the current in step III.

7. The method for monitoring bubble breakup during CMP according to claim 4, wherein from the start of the polishing in step II, if the magnitude of the monitored current is constant before the end of the polishing in step III, the friction force between the second surface of the first wafer and the polishing pad is changed from large to small from the start of polishing and then stabilized.

8. The method for monitoring bubble breakup during CMP according to claim 6, wherein the method further comprises step IV: triggering a machine alarm when the monitored current is increased instantaneously during polishing in step III.
